(19) United States
(12) Patent Application Publication
(10) Pub. No.: US 2008/0012548 A1
(43) Pub. Date: Jan. 17, 2008

(54) MEASURING DEVICE OF AN HF PLASMA SYSTEM

(75) Inventors: Christoph Gerhardt, Freiburg (DE); Daniel Krausse, Freiburg (DE); Peter Riessle, St. Margen (DE)

Correspondence Address: FISH & RICHARDSON PC, P.O. BOX 1022, MINNEAPOLIS, MN, 55440-1022, US

(73) Assignee: HUETTINGER ELEKTRONIK GMBH + CO. KG, Freiburg (DE)

(21) Appl. No.: 11/690,437

(22) Filed: Mar. 23, 2007

Related U.S. Application Data
(60) Provisional application No. 60/745,780, filed on Apr. 27, 2006.

(30) Foreign Application Priority Data
Mar. 25, 2006 (EP) EP 06 006 200.7

(51) Int. Cl. G01R 19/10; H04B 1/10

(52) U.S. Cl. 324/76.11; 327/551; 327/557; 327/558; 327/559

(57) ABSTRACT

A measuring device of an HF plasma system includes an uncoupling device for uncoupling one or a plurality of signals related to a power and at least one filter arrangement to which such a signal is transmitted. The filter arrangement is designed as a band pass filter arrangement and includes a first and a second filter element between which a decoupling device is arranged.

### CROSS REFERENCE TO RELATED APPLICATION

This application claims priority under 35 U.S.C. §119 (a) to European Application No. 06 006 200.7, filed on Mar. 25, 2006, and under 35 U.S.C. §119(e) from U.S. Provisional Application Ser. No. 60/745,780, filed Apr. 27, 2006. Both of these priority applications are hereby incorporated by reference in their entirety.

### TECHNICAL FIELD

The invention relates to a measuring device of an HF plasma system.

### BACKGROUND

High frequency (HF) plasma process excitation devices have an HF generator that supplies HF power to a plasma process (which is the plasma load). The HF power is generally supplied to the plasma process within a narrow band frequency range, in particular, for example, between about 10-30 MHz, or at about industrial frequencies of 13.56 MHz or 27.12 MHz. Measuring devices can be provided for measuring the power supplied to the plasma process. The supplied power, the current, the voltage, the impedance, or the phase between the current and voltage can be detected with the use of the measuring device in order to enable or facilitate regulation or control of the power.

There are different methods of determining the power supplied to the plasma load of an HF plasma process excitation system. For example, the measuring device can be a directional coupler. A directional coupler uncouples signals relating to the power (in particular, forward power Pᵢ supplied to the load and reflected power Pᵣ reflected from the plasma load). Voltage and current or impedance and the phase angle between the voltage and current can be measured.

The uncoupled signals are converted to a voltage signal that is related to the uncoupled signal, e.g., it is proportional to the root of the measured power.

The voltage signal from the directional coupler can be filtered using a low pass filter that includes inductances and capacitances of simple or higher order. The low pass filter is used to filter the high frequency portions of the power because such high frequency portions are generally present as interferences or harmonics in the transmission line. A low pass filter arrangement can be used when the measured signal is to be digitized, e.g., with an A-D converter. In plasma systems, low frequency interferences can occur that may also result in measured value errors.

### SUMMARY

In one general aspect, a measuring device is connected to a transmission line of an HF plasma system. The measuring device includes an uncoupling device for uncoupling one or a plurality of signals related to an HF signal, and at least one filter arrangement coupled to the uncoupling device to receive the uncoupled signal. The filter arrangement includes a first filter element, a second filter element, and a decoupling device between the first filter element and the second filter element.

Implementations can include one or more of the following features. For example, the filter arrangement can be a band pass filter arrangement. The first filter element can be a low pass filter and the second filter element can be a high pass filter. Both filter elements can be passive filters.

The measuring device can include an attenuator pad arranged between the first filter element and the uncoupling device.

The decoupling device can include an amplifier.

The filter arrangement can include a resistor element connected in series with the decoupling device. The resistance of the resistor element can be equal to the system resistance of the second filter element. The resistor element can be between the decoupling device and the second filter element.

The filter arrangement can include a second decoupling device in series with the second filter element. The second decoupling device can be between the second filter element and an output of the filter arrangement.

The measuring device can include a detector element that is connected to the filter arrangement.

The uncoupling device can include a first coupling line that uncouples the forward power to the plasma load, can a second coupling line that uncouples the reflected power from the plasma load. The filter arrangement can include two band pass filter arrangements each associated with the first or the second coupling line. The measuring device can include two attenuator pads each associated with one of the first and second coupling lines and each being connected between the coupling line and the respective band pass filter arrangement. The measuring device can include two detector elements each associated with a band pass filter arrangement to receive an output of the associated band pass filter arrangement. The measuring device can include a difference former at an output of the detector elements and configured to determine the difference between the forward power and the reflected power.

The uncoupling device can be a directional coupler including at least one coupling line. The characteristic wave impedance of the coupling line can be matched to the characteristic wave impedances of the transmission lines connected to it. The directional coupler can include one transmission line and two coupling lines. The coupling lines can be terminated at least at one end with a terminating resistor whose resistance value is approximately equal to the characteristic wave impedance of the coupling line.

The uncoupling device can be in a line that couples an HF generator to a plasma load.

In another general aspect, an HF plasma system includes an HF generator that supplies an HF power to a plasma load along a transmission line, and a measuring device. The measuring device includes an uncoupling device for uncoupling one or a plurality of signals related to an HF signal on the transmission line, and at least one filter arrangement coupled to the uncoupling device to receive the uncoupled signal. The filter arrangement includes a first filter element, a second filter element, and a decoupling device between the first filter element and the second filter element.

Implementations can include one or more of the following features. Both filter elements of the filter arrangement can be passive filters.

The measuring deice can include an attenuator pad arranged between the first filter element and the uncoupling device. The filter arrangement can include a resistance connected in series with the decoupling device, and the resistance can be equal to the system resistance of the second filter element.

The measuring device can include a detector element that is connected to the filter arrangement.

The uncoupling device can include a first coupling line that uncouples the forward power to the plasma load, and a second coupling line that uncouples the reflected power from the plasma load. The filter arrangement can include two band pass filter arrangements each associated with the first or the second coupling line. The measuring device can include two alternator pads each associated with one of the first and second coupling lines and each being connected between the associated coupling line and the band pass filter arrangement, and two detector elements each associated with a band pass filter arrangement to receive an output of the associated band pass filter arrangement.

The measuring device can include a difference former at an output of the detector elements and configured to determine the difference between the forward power and the reflected power.

In another general aspect, power delivered by an HF generator to a plasma load along a transmission line is measured by uncoupling an HF signal on the transmission line, filtering high frequency parts of the uncoupled signal to output a first filtered signal, decoupling the first filtered signal, and filtering low frequency parts of the decoupled filtered signal to output a second filtered signal.

Implementations can include one or more of the following features. For example, the method can include attenuating the uncoupled signal prior to the high frequency filtering. The method can include decoupling the second filtered signal. The second filtered signal can be decoupled by amplifying the second filtered signal. The first filtered signal can be decoupled by amplifying the first filtered signal. The method can include detecting a power value associated with the second filtered signal. The HF signal on the transmission line can be uncoupled by uncoupling a forward power signal from the HF generator to the plasma load. The HF signal on the transmission line can be uncoupled by uncoupling a reflected power signal from the plasma load.

The method can include uncoupling a reflected power signal from the plasma load, filtering high frequency parts of the uncoupled reflected power signal to output a first filtered reflected signal, decoupling the first filtered reflected signal, and filtering low frequency parts of the decoupled filtered reflected signal to output a second filtered reflected signal. The method can also include detecting a forward power value associated with the second filtered signal, detecting a reflected power value associated with the second filtered reflected signal, and calculating a difference between the forward power value and the reflected power value.

In the measuring device of the HF plasma system, HF signals, or physical values associated with them, can be determined more accurately.

In one general aspect, measuring device includes a filter arrangement that is designed as a band pass filter arrangement and includes a first and second filter element between which a decoupling device is arranged. The advantage of a band pass filter is that both low frequency and high frequency interferences, which may lead to measured value errors, can be reduced or eliminated. A decoupling device is provided between the filter elements to reduce ripple and measuring deviations dependent on frequency. The band pass filter is constructed of a plurality of filter elements, preferably of a series connection of a plurality of filter elements. This design allows adjusting the characteristics of the first filter element independently of the characteristics of the second filter element, and vice versa. An extremely flat pass band of low attenuation can be obtained, which means that the attenuation is constant over a wide frequency range, with no or only slight ripple occurring. The HF signal can be a signal related to an HF power, for example an HF current or an HF voltage.

The first filter element can be designed as a low pass filter and the second filter element can be designed as a high pass filter. The high frequency parts of the signal describing the HF signal can be filtered by the low pass filter, thus preventing or inhibiting high frequency portions from reaching the decoupling device. The decoupling device need not be designed for high frequencies, which renders the band pass filter arrangement inexpensive and uncritical in terms of tendencies to oscillate. The remaining low frequency interferences can be filtered out by the high pass filter connected downstream of the decoupling device. The filter elements can be passive filters. Passive filters with a higher order Tschebyscheff characteristic are preferably used to achieve sufficiently steep flanks for adequate attenuation of harmonics and at the same time to ensure a pass band for a predetermined bandwidth dependent on frequency variability and pulse frequency.

The limit frequencies of the band pass filter arrangement can be adjustable to enable the band pass filter arrangement to be designed for different requirements. Thus, by a suitable choice of limit frequencies, the band pass filter arrangement is suitable for measuring the power of an HF generator with a fixed frequency, e.g., 13.56 MHz, or with correspondingly other selected fundamental frequencies of ran HF generator with frequency variability or for an HF generator that is operated in a pulsed fashion. The limit frequencies for the first and second filters can be adjusted independently of each other without altering the attenuation curve.

During commissioning, the power measuring device can be finely adjusted if the filter elements are also adjustable. The filter elements can be adjustable independent from one another.

In some implementations, an attenuator pad is arranged before the first element or before the band pass filter arrangement. Matching is improved in a broad band by the attenuator pad. “Broad band improvement” means that the matching is also improved for frequency portions that are not to be measured, which may be desirable since the undesirable frequency portions can also result in reflections and hence result in measurement errors if the matching is poor. The first filter element, for example, is designed as a low pass filter, and consequently blocks all higher frequency signals. However, since the low pass filter does not absorb the higher frequency signals, it reflects them back to the attenuator pad. The higher an attenuation factor of the attenuator pad, the fewer of these reflected signals are fed back to the uncoupling device. The fewer signals are reflected back to the uncoupling device the smaller is the measured value deviations. A high attenuation factor at this point is therefore advantageous. The attenuation also improves uniformity in the pass band, i.e., the ripple in the pass band is reduced. A residual ripple of about 0.064 dB, at least about 0.008 dB, and a maximum of about 0.108 dB can be obtained with a 10 dB attenuator pad in the range of 11.8 MHz to 15.3 MHz.

The attenuator pad can be designed for a system resistance, which can be arbitrarily selected. For example, a line can be arranged between the decoupling device and the attenuator pad. Since high frequency signals are transmitted through this line, a characteristic wave impedance is taken into account for this line. The system resistance of the attenuator pad can be selected to be equal to the characteristic wave impedance of the line, thereby eliminating or reducing reflections due to mismatching. A very common resistance value for characteristic wave impedances and system resistances in lines, connections, and measuring means in HF technology is 50 ohms, and for this reason, the system resistance of the attenuator pad can be selected to be 50 ohms. The attenuator pad can take any form, for example, a H- or a T-arrangement of resistances. However, the attenuator pad can also have a resistance transformation if this is required or if it is desirable for the first filter element or the band pass filter arrangement. The first filter element itself also has a system resistance, which can differ from the system resistance of the attenuator pad. The attenuator pad can be designed so that it has a resistance transformation from the system resistance of the attenuator pad to the system resistance of the filter element.

The decoupling device can have an amplifier for compensating the attenuation effected by the first filter element in the pass band. The amplification factor is preferably arbitrarily adjustable. To ensure a sufficiently high signal to noise ratio, the attenuator pad can be designed so that the signal levels after the attenuator pad are not too low. Consequently the amplification of the decoupling device can also be set relatively low, e.g., between 0 and 6 dB.

In some implementations, a terminating resistance, whose resistance value is equal to the system resistance of the respective filter element, is provided at the output of the first and/or the second filter element. The terminating resistance should be as broad band as possible, i.e., not only is it effective in the measuring range but also in the frequency ranges in which the filter elements produce an attenuation. This also improves matching and reduces interferences due to reflection.

A resistance that is equal to the system resistance of the second filter element can be connected in series at the output of the decoupling device. This resistance should also be as broad band as possible, i.e., it should be constant over a defined frequency range that is preferably greater than the pass band of the band pass filter arrangement in offer to suppress interferences due to reflection.

In some implementations, a second decoupling device can be arranged downstream from the second filter element. In this case, the filter element is not loaded and changed in its characteristics by the subsequent circuit. The output of the second decoupling device is preferably the band pass filtered signal.

In some implementations, a detector element is provided and is connected downstream of the band pass filter arrangement. The detector element generates a DC signal from the filtered signal and the DC signal is clearly related to the uncoupled signal, e.g., to the uncoupled forward power, the reflected power or the voltage, current, impedance, or phase angle between voltage and current.

Further advantages are gained if for a signal describing the forward power Pᵢ and for a signal describing the reflected power Pᵣ, respectively, a band pass filter arrangement, in particular preference, a band pass filter arrangement with respectively an upstream connected attenuator pad, in particular preference, with respectively a downstream detector element, is provided. The band pass filter arrangement enables band pass filtered signals to be generated for both powers, and the power P_{L} supplied to the load can be determined very or more accurately.

In some implementations, a difference former is provided or determining the difference from Pᵢ and Pᵣ. The difference former is preferably connected downstream from the detector elements.

Pᵢ and/or Pᵣ can be uncoupled easily and inexpensively if the uncoupling device is designed as a directional coupler. The directional coupler has a transmission line through which flows the current of the power to be determined. Furthermore, the directional coupler has at last one coupling line for uncoupling the forward power and the reflected power. However, one coupling line can be provided for uncoupling the forward power and another for uncoupling the reflected power. The characteristic wave impedance of the coupling lines can be designed for the characteristic wave impedance of the lines connected to it. By matching to the characteristic wave impedance, reflections can be reduced and good matching is achieved.

The use of two coupling lines enables Pi and Pr to be uncoupled separately. Moreover, Pi and Pr can be uncoupled with different coupling factors, where the coupling factor for each coupling line relates to the portion of power that is coupled out of the transmission line.

The coupling lines can be terminated, at least at one end, with a terminating resistor whose resistance value is equal to the characteristic wave impedance of the coupling line. The terminating resistor prevents or reduces reflections, thereby improving accuracy in measured results. Preferably only the terminating resistor is provided at one end of the coupling lines, respectively. If the terminating resistors are adjustable, then fine adjustment can be carried out.

An HF plasma system can include an HF generator that applies an HF power to a plasma load, and a power measuring device such as previously described.

Further characteristics and advantages of the invention are evident from the following description of exemplary embodiments of the invention, with reference to the figures in the drawing which show details essential to the invention, and from the claims. The individual characteristics may be achieved individually or a plurality of features may be achieved in any combination in a variant of the invention.

Preferred exemplary embodiments of the invention are represented diagrammatically in the drawing and are explained in greater detail in the following with reference to the figures in the drawing.

### DESCRIPTION OF THE DRAWINGS

FIG. 1 is a block diagram of an HF plasma system;

FIG. 2 is a block diagram of a measuring device that can be used in the HF plasma system of FIG. 1;

FIG. 3 is a block diagram of band pass filter arrangements of the measuring device of FIG. 2;

FIG. 4 is a graph of an attenuation curve for a band pass filter arrangement including an attenuator pad;

FIG. 5 is a graph of an attenuation curve for a band pass filter arrangement that does not include an attenuator pad;

FIG. 6 is a graph of the reflection factor and the standing wave ratio of a band pass filter arrangement including an upstream attenuator pad;

FIG. 7 is a graph of the reflection factor and the standing wave ratio of a band pass filter arrangement that does not include an upstream attenuator pad;

FIG. 8 is a block diagram of an attenuator pad in a II-connection;

FIG. 9 is a block diagram of an attenuator pad in a T-connection;

FIG. 10 is a block diagram of a filter element with low pass characteristics; and

FIG. 11 is a block diagram of a filter element with high pass characteristics.

### DETAILED DESCRIPTION

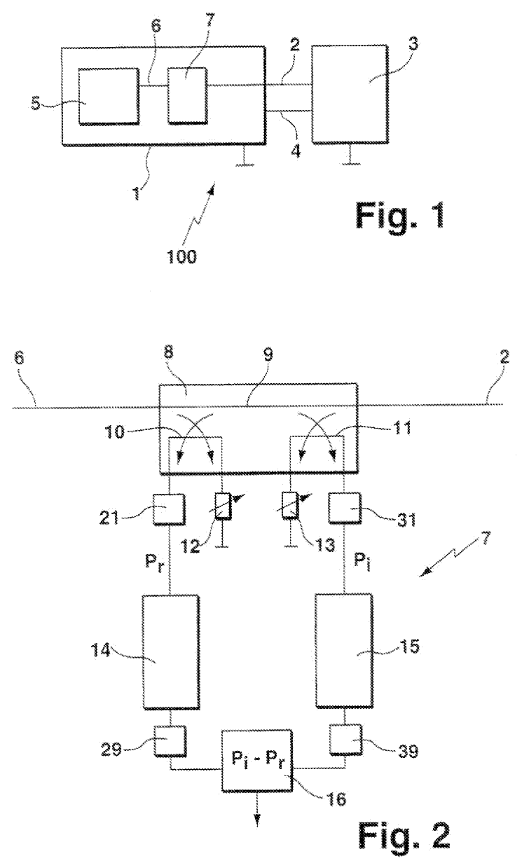

FIG. 1 shows a HF plasma process excitation device 1 of an HF plasma system 100. The HF plasma process excitation device 1 is connected by a line 2 to a load 3. Line 4 represents a ground connection. HF power is transmitted through line 2 to load 3. HF plasma process excitation device 1 includes an HF generator 5 and a measuring device 7 that are connected to each other by a line 6. Measuring device 7 can be a device that measures power supplied to load 3, and therefore measuring device 7 can be connected between HF generator 5 and load 3. An impedance matching, not shown, can be arranged between HF plasma process excitation device 1 and load 3.

Measuring device 7 can also be arranged outside HF plasma process excitation device 1, but it is advantageous to arrange it inside HF plasma process excitation device 1, as shown in FIG. 1, because it can then be used directly for regulating HF generator 5.

FIG. 2 shows measuring device 7, which represents a power measuring device. Measuring device 7 includes an uncoupling device 8 that is designed as a directional coupler. Uncoupling device 8 has a transmission line 9 that is connected to line 6 and to line 2. A first coupling line 10 and a second coupling line 11 are provided parallel to transmission line 9. Coupling line 10 serves to uncouple reflected power Pᵣ, which is the power reflected by the plasma load 3 or a signal related to it. Coupling line 11 serves to uncouple forward power Pᵢ, which is the power derived from the HF generator 5 or a signal related to it. Coupling lines 10, 11 each have a terminating resistor 12, 13 on one end. Terminating resistors 12, 13 are designed so that their resistance values are adjustable and can be set to be equal to a characteristic wave impedance of uncoupling device 8. Each coupling line 10, 11 is connected to a band pass filter arrangement 14, 15 in which the signals describing, respectively, reflected power Pᵣ and forward power Pᵢ are filtered. Attenuator pads 21 and 31 are each connected upstream and detector elements 29 and 39 are each connected downstream from band pass filter arrangements 14 and 15, respectively. The power values determined in band pass filter arrangements 14, 15 are transmitted to a difference former 16, where the difference between Pᵢ and Pᵣ is determined. The difference Pᵢ−Pᵣ represents power P_{L} supplied to load 3. The measured power P_{L} can be used to control and/or regulate HF generator 5. For example, the measure power P_{L} is input to a controller that is configured to maintain a constant power supply to the plasma load, or that determines from the power delivered to the plasma load (in the plasma chamber) whether or not the plasma is ignited and reacts accordingly, for example, by decreasing the forward power in order to reduce the reflected power.

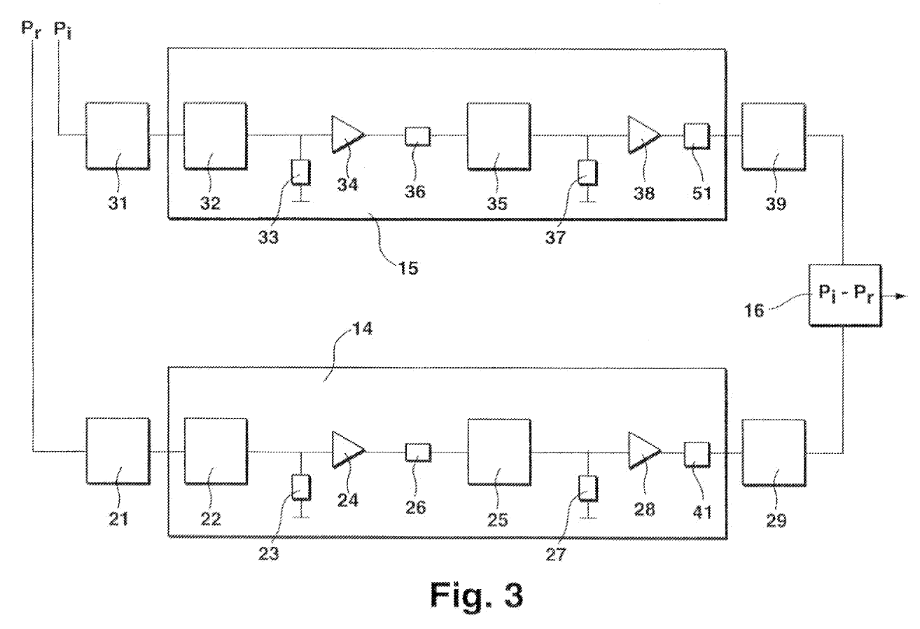

FIG. 3 shows band pass filter arrangements 14, 15 in detail, these arrangements being of analog construction. The signals derived from uncoupling device 8 are first transmitted to attenuator pad 21, 31, which attenuates or reduces the signal levels. Output of attenuator pad 21, 31 is fed, respectively, to first filter elements 22, 32 of band pass filter arrangements 14, 15. Attenuator pads 21, 31 can have an input resistance that is equal to the characteristic wave impedance of the connecting line between attenuator pads 21, 31 and coupling lines 10 and 11 of uncoupling device 8. For example, for lines and connection in HF technology that are normally in 50 ohm technology, the input resistance of attenuator pads 21, 31 can be equal to 50 ohms.

The first filter element 22, 32 has a system resistance. The output of attenuator pads 21, 31 is designed for this system resistance, and if necessary, attenuator pad 21, 31 carries out a resistance transformation. The first filter element 22, 32 can be designed as a low pass filter, and is in turn terminated with, respectively, a terminating resistor 23, 33 whose resistance value can be equal to the system resistance of the first filter element 22, 32, respectively.

A first decoupling device 24, 34, designed as an amplifier, is arranged downstream from the first filter elements 22, 32, respectively. The amplification factor of decoupling devices 24, 34 can be adjustable. A resistance 26, 36, which is adjusted to the system resistance of second filter elements 25, 35, respectively, follows the decoupling devices 24, 34. Second filter elements 25, 35 are connected downstream from resistance 26, 36 and are designed as high pass filters. Second filter elements 25, 35 have a terminating resistor 27, 37, respectively. Resistances 26, 27, 36, 37 can be equal to the system resistance of second filter element 25, 35.

Second decoupling devices 28, 38, which can be designed as amplifiers, are connected downstream from respective second filter elements 25, 35. The advantage of using a second decoupling device 28, 38 is that the second filter elements 25, 35 are less or not at all influenced by circuits connected to respective band pass filter arrangements 14, 15. The band pass filtered signals, which describe the forward power and the reflected power, lie at the outputs of second decoupling devices 28, 38. Resistances 41 and 51, which correspond to the system resistance of the circuit that is downstream of the resistances 41 and 51 (such as the detector elements 29, 39, the difference former 16, and the controller), are connected downstream of respective second decoupling devices 28, 38. Band pass filter arrangements 14, 15 therefore include, respectively, filter elements 22, 32; 25, 35; resistances 23, 33; 26, 36; 27, 37; 41, 51; and decoupling devices 24, 34; 28, 38. Detector elements 29, 39, in which the corresponding power value can be determined either directly or by conversion (for example, calculated from measured values such as voltage and/or current), are connected downstream of respective band pass filter arrangements 14, 15. The difference between the power values Pᵢ and Pᵣ can be determined in difference former 16.

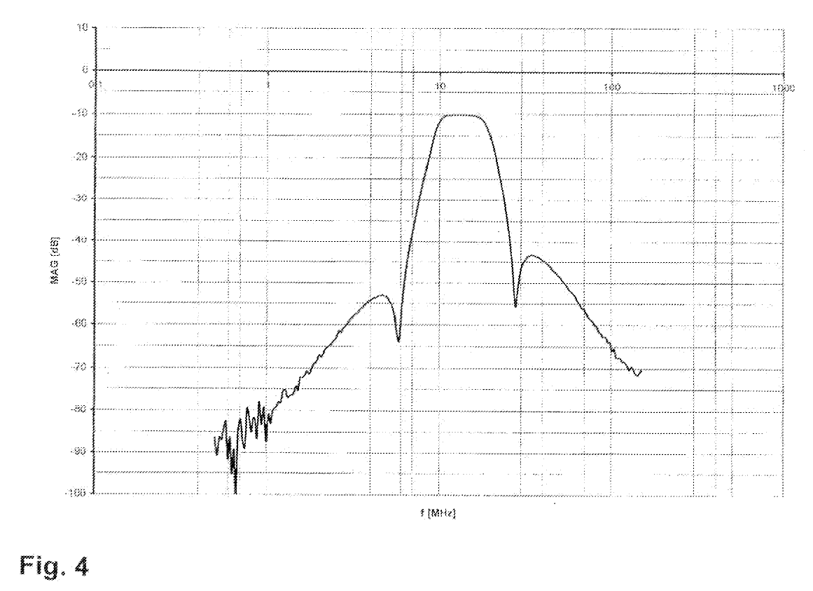

FIG. 4 shows, by way of example, the attenuation curve of the voltage transfer function of a band pass filter arrangement 14, 15 including an upstream attenuator pad 21, 31, depending on frequency. The pass band lies between approximately 10 and 15 MHz, the cure being very flat in this pass band and having hardly any ripple. The attenuation in this range is therefore essentially constant. In this range the attenuation is approximately −6 dB. Outside this range the attenuation curve has steeply falling flanks with an attenuation of over 40 dB for frequencies greater than 20 MHz and lower than 6 MHz. The attenuator pad 21, 31 help reduce or prevent deterioration in attenuation at higher frequencies.

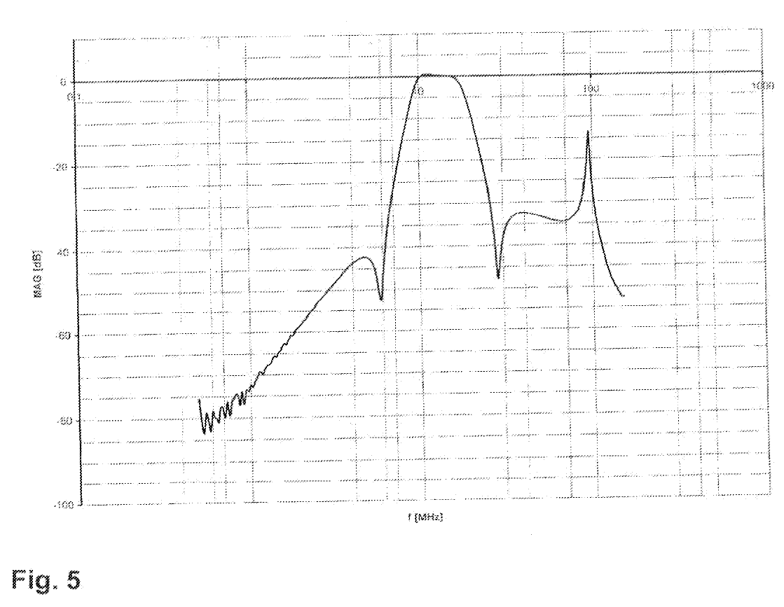

For comparison, FIG. 5 shows an attenuation curve of the voltage transfer function of a band pass filter arrangement 14, 15 that does not include an upstream attenuator pad 21, 31, depending on frequency. The inadequate attenuation at frequencies above 100 MHz can be seen in this graph. The substantially reduced uniformity in the pass band can also be seen in this graph. The attenuation renders the band pass filter in the pass band constant.

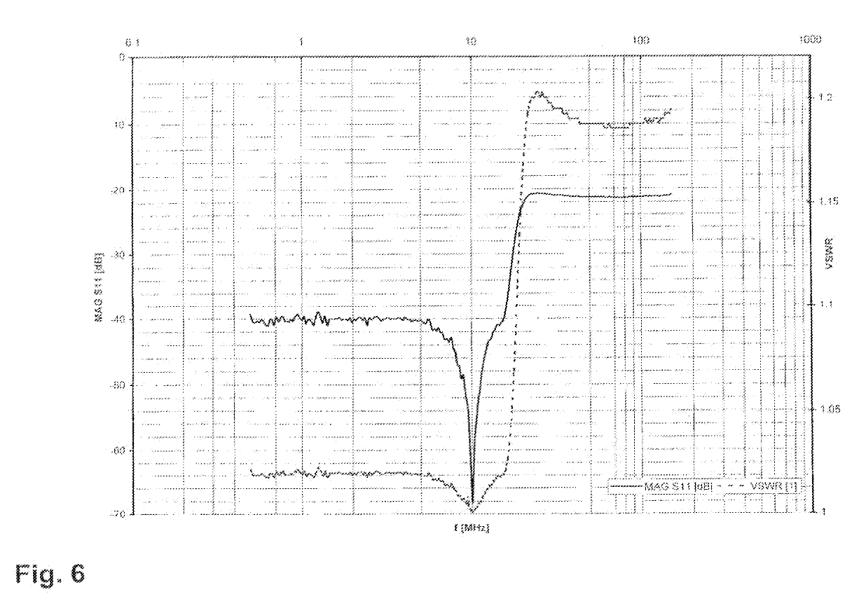

FIG. 6 shows the curve of the standing wave ratio (dashed line) and reflection factor (continuous line) of a band pass filter arrangement 14, 15 including an upstream attenuator pad 21, 31, depending on frequency. The standing wave ratio is the ratio of the amplitude of a partial standing wave at an antinode (maximum), in the transmission line. The standing wave ratio can be defined as a voltage ratio (called a voltage standing wave ratio or VSWR). Or, the standing wave ratio can be defined in terms of current. As another example, the power standing wave ratio is the square of the VSWR.

The voltage component of a standing wave in a uniform transmission line consists of the forward wave superimposed on the reflected wave. Reflections occur as a result of discontinuities, such as an imperfection in an otherwise uniform transmission line, or when a transmission line is terminated with other than its characteristic impedance. Thus, a reflection factor can be defined as a ratio of the voltage amplitude of the forward wave to the voltage amplitude of the reflected wave and it describes a magnitude (MAG) and a phase shift of the reflection.

FIG. 7 shows the curve of the standing wave ratio (dashed line) and of the reflection factor (continuous line) of a band pass filter arrangement 14, 15 that does not include an upstream attenuator pad 21, 31. The dashed line shows the standing wave ratio (in this case, the VSWR). The VSWR should be close to 1 for the best possible input matching. The increase above 15 MHz in FIG. 6 with an upstream attenuator pad to values of approximately 1.2 should be noted, whereas values of over 200 are obtained in FIG. 7. The continuous line shows the curve of the magnitude (MAG) of the reflection factor S11 [dB]. It should be as low as possible, advantageously lower than 20 dB. As can be seen in FIG. 6, this is reliably obtained with an upstream attenuator pad up to over 100 MHz, whereas a reflection factor close to 0 dB ensures almost complete reflections above 20 MHz without an upstream attenuator pad (FIG. 7).

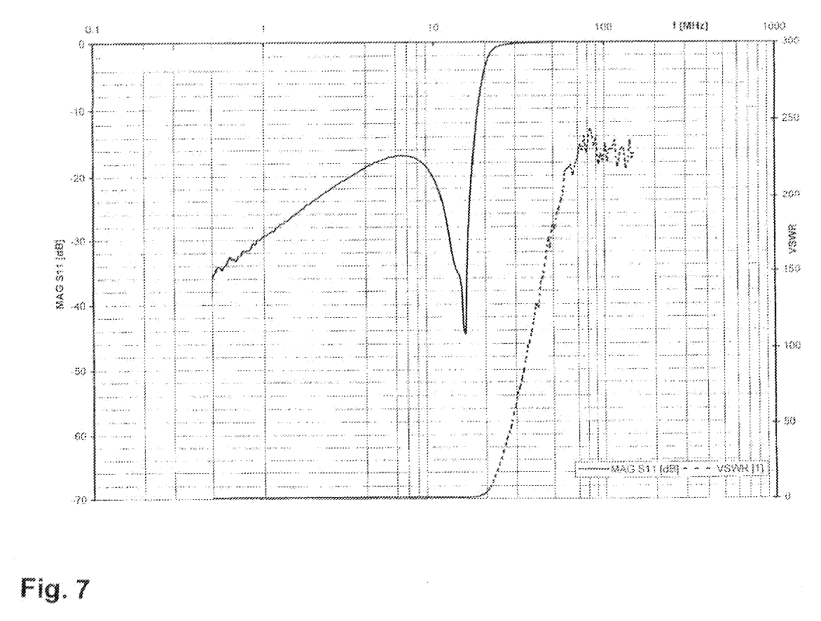

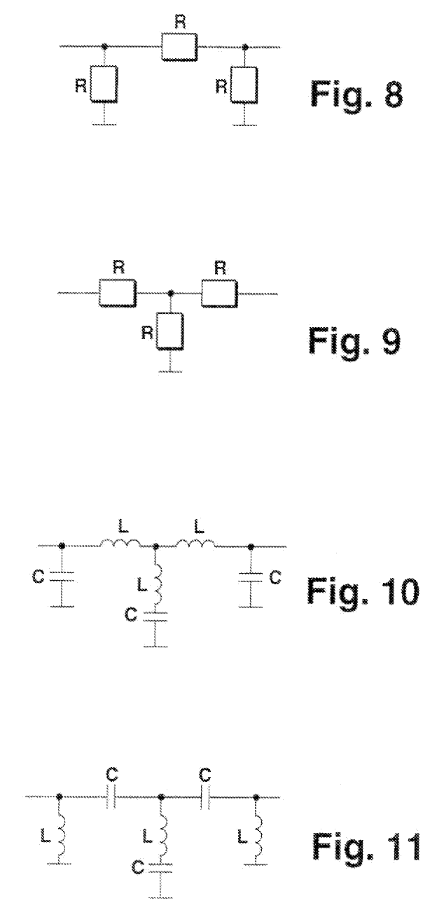

Referring to FIG. 8, in some implementations, attenuator pad 21, 31 can be in II-form, consisting of three resistances R. Referring to FIG. 9, in some implementations, attenuator pad 21, 31 can be in T- form, consisting of three resistances R.

Referring to FIG. 10, in some implementations, passive filter element 22, 32; 25, 35 can include inductances L and capacitances C, with low pass characteristics.

Referring to FIG. 11, in other implementations, passive filter element 22, 32; 25, 35 can include inductances L and capacitances C, with high pass characteristics.

### OTHER EMBODIMENTS

It is to be understood that while the invention has been described in conjunction with the detailed description thereof, the foregoing description is intended to illustrate and not limit the scope of the invention, which is defined by the scope of the appended claims. Other aspects, advantages, and modifications are within the scope of the following claims.

What is claimed is:

1. An HF plasma system, the measuring device comprising:
an uncoupling device for uncoupling one or a plurality of signals related to an HF signal; and
at least one filter arrangement coupled to the uncoupling device to receive the uncoupled signal;
wherein the filter arrangement comprises:
a first filter element;
a second filter element;
a decoupling device between the first filter element and the second filter element.

2. The measuring device of claim 1, wherein the first filter element is a low pass filter and the second filter element is a high pass filter.

3. The measuring device of claim 1, wherein both filter elements are passive filters.

4. The measuring device of claim 1, wherein the filter arrangement is a band pass filter arrangement.

5. The measuring device of claim 1, further comprising an attenuator pad arranged between the first filter element and the uncoupling device.

6. The measuring device of claim 1, wherein the decoupling device includes an amplifier.

7. The measuring device of claim 1, wherein the filter arrangement includes a resistor element connected in series with the decoupling device, wherein the resistor element has a resistance that is equal to the system resistance of the second filter element.

8. The measuring device of claim 7, wherein the resistor element electrically connects the decoupling device and the second filter element.

9. The measuring device of claim 1, wherein the filter arrangement includes a second decoupling device in series with the second filter element.

10. The measuring device of claim 9, wherein the second decoupling device is between the second filter element and an output of the filter arrangement.

11. The measuring device of claim 1, further comprising a detector element that is connected to the filter arrangement.

12. The measuring device of claim 1, wherein the uncoupling device comprises:
a first coupling line that uncouples forward power to the plasma load; and
a second coupling line that uncouples reflected power from the plasma load;
wherein the filter arrangement includes two band pass filter arrangements each associated with the first or the second coupling line.

13. The measuring device of claim 12, further comprising:
two attenuator pads each associated with one of the first and second coupling lines and connected between the coupling line and the band pass filter arrangement; and
two detector elements each associated with a band pass filter arrangement to receive an output of the associated band pass filter arrangement.

14. The measuring device of claim 12, further comprising a difference former at an output of the detector elements and configured to determine a difference between the forward power and the reflected power.

15. The measuring device of claim 1, wherein the uncoupling device is a directional coupler including at least one coupling line, wherein a characteristic wave impedance of the coupling line is matched to a characteristic wave impedances of the transmission lines connected to it.

16. The measuring device of claim 15, wherein the directional coupler includes one transmission line and two coupling lines.

17. The measuring device of claim 15, wherein the coupling lines are terminated at lest at one end with a terminating resistor whose resistance value is approximately equal to the characteristic wave impedance of the coupling line.

18. The measuring device of claim 1, wherein the uncoupling device is in a line that couples an HF generator to a plasma load.

19. The measuring device of claim 18, wherein the uncoupling device uncouples a signal related to a power delivered by the HF generator the plasma load.

20. The measuring device of claim 18, wherein the uncoupling device uncouples a signal related to power reflected by the plasma load.

21. An HF plasma system comprising:
an HF generator that supplies an HF power to a plasma load along a transmission line, and
a measuring device comprising:
an uncoupling device for uncoupling one or a plurality of signals related to an HF signal on the transmission line; and
at least one filter arrangement coupled to the uncoupling device to receive the uncoupled signal, wherein the filter arrangement comprises a filter arrangement that comprises a first filter element, a second filter element, and a decoupling device between the first filter element and the second filter element.

22. The system of claim 21, wherein both filter elements of the filter arrangement are passive filters.

23. The system of claim 21, wherein the measuring device comprises an attenuator pad arranged between the first filter element and the uncoupling device.

24. The system of claim 21, wherein the filter arrangement includes a resistor element connected in series with the decoupling device, wherein the resistor element has a resistance is equal to the system resistance of the second filter element.

25. The system of claim 21, wherein the measuring device comprises a detector element that is connected to the filter arrangement.

26. The system of claim 21, wherein the uncoupling device comprises:
a first coupling line that uncouples the forward power to the plasma load; and
a second coupling line that uncouples the reflected power from the plasma load;
wherein the filter arrangement includes two band pass filter arrangements each associated with the first or the second coupling line.

27. The system of claim 26, wherein the measuring device comprises:
two attenuator pads each associated with one of the first and second coupling lines and each being connected between the associated coupling line and the band pass filter arrangement; and
two detector elements each associated with a band pass filter arrangement to receive an output of the associated band pass filter arrangement.

28. The system of claim 26, wherein the measuring device comprises a difference former at an output of the detector elements and configured to determine the difference between the forward power and the reflected power.

29. A method of measuring power delivered by an HF generator to a plasma load along a transmission line, the method comprising:
uncoupling an HF signal on the transmission line;
filtering high frequency parts of the uncoupled signal to output a first filtered signal;
decoupling the first filtered signal; and
filtering low frequency parts of the decoupled filtered signal to output a second filtered signal.

30. The method of claim 29, further comprising attenuating the uncoupled signal prior to the high frequency filtering.

31. The method of claim 29, further comprising decoupling the second filtered signal.

32. The method of claim 29, wherein decoupling the second filtered signal comprises amplifying the second filtered signal.

33. The method of claim 29, wherein decoupling the first filtered signal comprises amplifying the first filtered signal.

34. The method of claim 29, further comprising detecting a power value associated with the second filtered signal.

35. The method of claim 29, wherein uncoupling the HF signal on the transmission line includes uncoupling a forward power signal from the HF generator to the plasma load.

36. The method of claim 35, further comprising:
uncoupling a reflected power signal from the plasma load;
filtering high frequency parts of the uncoupled reflected power signal to output a first filtered reflected signal;
decoupling the first filtered reflected signal; and
filtering low frequency parts of the decoupled filtered reflected signal to output a second filtered reflected signal.

37. The method of claim 36, further comprising:
detecting a forward power value associated with the second filtered signal;
detecting a reflected power value associated with the second filtered reflected signal; and
calculating a difference between the forward power value and the reflected power value.

38. The method of claim 29, wherein uncoupling the HF signal on the transmission line includes uncoupling a reflected power signal from the plasma load.
